(19) United States
(12) Patent Application Publication
(10) Pub. No.: US 2018/0130768 A1
(43) Pub. Date: May 10, 2018

(54) Substrate Based Fan-Out Wafer Level Packaging

(71) Applicant: Unisem (M) Berhad, Kuala Lumpur (MY)

(72) Inventors: Kim Heng Tan, Kuala Lumpur (MY); Chan Wah Chai, Ipoh (MY); Kwai Hong Wong, Ipoh (MY)

(73) Assignee: Unisem (M) Berhad, Kuala Lumpur (MY)

(21) Appl. No.: 15/399,525

(22) Filed: Jan. 5, 2017

Related U.S. Application Data
(63) Continuation-in-part of application No. 15/347,253, filed on Nov. 9, 2016.

(51) Int. Cl. H01L 23/00; H01L 21/48; H01L 21/56; H01L 23/498

(52) U.S. Cl. CPC H01L 24/97; H01L 21/486; H01L 21/4853; H01L 21/561; H01L 24/81; H01L 2224/81192; H01L 23/49838; H01L 23/49827; H01L 23/49816; H01L 2924/15331; H01L 21/481

(57) ABSTRACT

A method and apparatus for manufacturing substrate based fan-out wafer level packaging is provided. The method includes providing a substrate, applying a first photoresist pattern, depositing copper or a copper alloy, applying a second photoresist pattern, forming chip attach site pillars by depositing a layer of copper or copper alloy, and attaching a semiconductor device via a flip chip bonding. The attaching includes forming a plurality of interconnect bumps between the semiconductor device and the chip attach site and forming a space between the semiconductor device and the substrate. The method further includes encapsulating the semiconductor device, thinning a second side of the substrate, applying a ball grid array pattern on the second side and etching the second side with copper, applying a solder mask coating, attaching a plurality of ball drops, and singulating a unit.

### CROSS-REFERENCE TO RELATED APPLICATION:

This application is a continuation-in-part of application Ser. No. 15/347,253, filed Nov. 9, 2016 and entitled “Substrate Based Fan-Out Wafer Level Packaging,” the contents of which are incorporated herein by reference in its entirety.

### BACKGROUND OF THE INVENTION

### Field of the Invention

This invention relates to semiconductor device packages. More particularly, this invention relates to a fan-out wafer level semiconductor device package.

### Description of the Related Art

Molded plastic packages provide environmental protection to integrated circuit devices (dies). Such packages typically include at least one semiconductor device (die) having its input/output (I/O) pads electrically connected to a lead frame type substrate or an interposer type substrate, with a molding compound coating the die and at least a portion of the substrate. Typically, the I/O pads on the die are electrically connected to bond sites on the substrate using either a wire bonding, tape bonding, or flip-chip bonding method. The lead frame or interposer substrate transmits electrical signals between the I/O pads and an electrical circuit external to the package.

Fan-out wafer level packaging (FOWLP) provides for multiple dies with a higher integration level and a greater number of external contacts. Conventional FOWLP allows for a smaller package, while increasing the number of I/O connections. Particularly, the die is encapsulated in a material, such as a composite including epoxy resin. A redistribution layer (RDL) is then formed on the die and on the encapsulant. The RDL re-route's I/O connections on the die to the periphery of the encapsulant.

As a result, FOWLP provides for a thinner profile as compared to wafer level packaging, and an increase in I/O connections, while improving thermal and electrical performance. However, standard FOWLP processes often result in reconstituted wafer warpage resulting from heat processing, or die movement during the encapsulation process or handling. The result is a waste of wafer materials, increasing the cost of manufacturing.

U.S. Pat. No. 7,915,741, titled “Solder bump UBM structure” and commonly owned with the present application, discloses an under bump metallization structure to improve stress on semiconductor devices, and is incorporated herein by reference in its entirety. This patent, however does not address the need for a FOWLP that reduces chip wastage by attaching the semiconductor device directly to the interconnect bumps and eliminates shifting during the molding process.

U.S. Pat. No. 7,795,710, titled “Lead frame routed chip pads for semiconductor packages” and commonly owned with the present application, discloses a method for patterning external and internal lead ends and routing circuits from a single electrically conductive substrate, and is incorporated herein by reference in its entirety. This patent, however does not address the need for a FOWLP that reduces chip wastage by attaching the semiconductor device directly to the interconnect bumps and eliminates shifting during the molding process.

It would be advantageous, therefore, to provide for FOWLP that solves these problems by reducing chip wastage.

### BRIEF SUMMARY OF THE INVENTION

In accordance with a first embodiment of the invention, there is provided a method for manufacturing substrate based fan-out wafer level packaging. The method includes (a) providing a substrate, (b) applying a first photoresist pattern, (c) depositing copper or a copper alloy on said first photoresist pattern, (d) applying a second photoresist pattern, (e) forming chip attach site pillars by depositing a layer of copper or copper alloy on said second photoresist pattern, (f) attaching a semiconductor device via a flip chip bonding, the attaching including forming a plurality of interconnect bumps between the semiconductor device and the chip attach site, and forming a space between the semiconductor device and the substrate, (g) encapsulating the semiconductor device with a protective layer compound, (h) thinning a second side of the substrate, the thinning including copper etching and thinning, (i) applying a ball grid array pattern on the second side, (j) etching the second side with copper, (k) applying a solder mask coating, (l) attaching a plurality of ball drops, and (m) singulating a unit.

In accordance with a second embodiment of the invention, there is provided a substrate based fan-out wafer level packaging. The packaging includes a substrate. The packaging further includes a first photoresist pattern adapted to be applied to the substrate, a copper or copper alloy layer adapted to be applied on top of the first photoresist pattern, and a second photoresist pattern adapted to be applied above the copper or copper alloy layer. A plurality of chip attach site pillars including a plurality of interconnect bumps are then formed on top of the second photoresist pattern, and a semiconductor device is adapted for placement above the interconnect bumps. The packaging further includes a protective layer that forms an encapsulant around the semiconductor device. A ball grid array (BGA) pattern is the applied to a second side of the copper of the substrate, with a solder mask coating applied below the BGA pattern, and a plurality of solder balls attached to the solder mask coating.

The details of one or more embodiments of the invention are set forth in the accompanying drawings and the description below. Other features, objects and advantages of the invention will be apparent from the description and drawings, and from the claims.

### BRIEF DESCRIPTION OF THE DRAWINGS

The invention will be more fully understood from the following detailed description taken in conjunction with the accompanying drawings wherein like elements are numbered alike, and in which:

FIG. 1 illustrates a substrate and protective layer in accordance with the invention;

FIG. 2 illustrates a first pattern application in accordance with the invention;

FIG. 3 illustrates application of copper plating in accordance with the invention;

FIG. 4 illustrates a second pattern application in accordance with the invention;

FIG. 5 illustrates formation of pillar bumps in accordance with the invention;

FIG. 6 illustrates the flip chip attachment in accordance with the invention;

FIG. 7 illustrates application of a protective layer in accordance with the invention;

FIG. 8 illustrates the thinning process in accordance with the invention;

FIG. 9 illustrates BGA pattern application in accordance with the invention;

FIG. 10 illustrates copper etching in accordance with the invention;

FIG. 11 illustrates solder mask coating in accordance with the invention;

FIG. 12 illustrates ball drop in accordance with the invention;

FIG. 13 illustrates unit singulation in accordance with the invention; and

FIG. 14 is another view of a portion of the invention.

FIG. 15 illustrates exemplary stress relief patterns in accordance with the invention.

### DETAILED DESCRIPTION

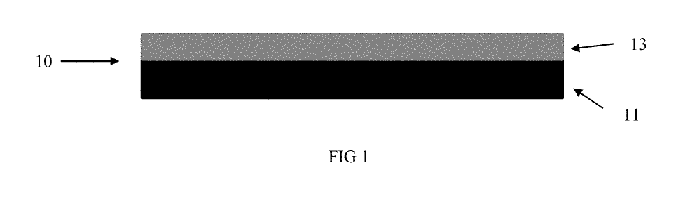

FIG. 1 illustrates a cross-sectional view of an electrically conductive substrate 10 that is to be patterned into a lead frame. The lead frame is used to route electrical signals in a semiconductor package, which encases at least one semiconductor device.

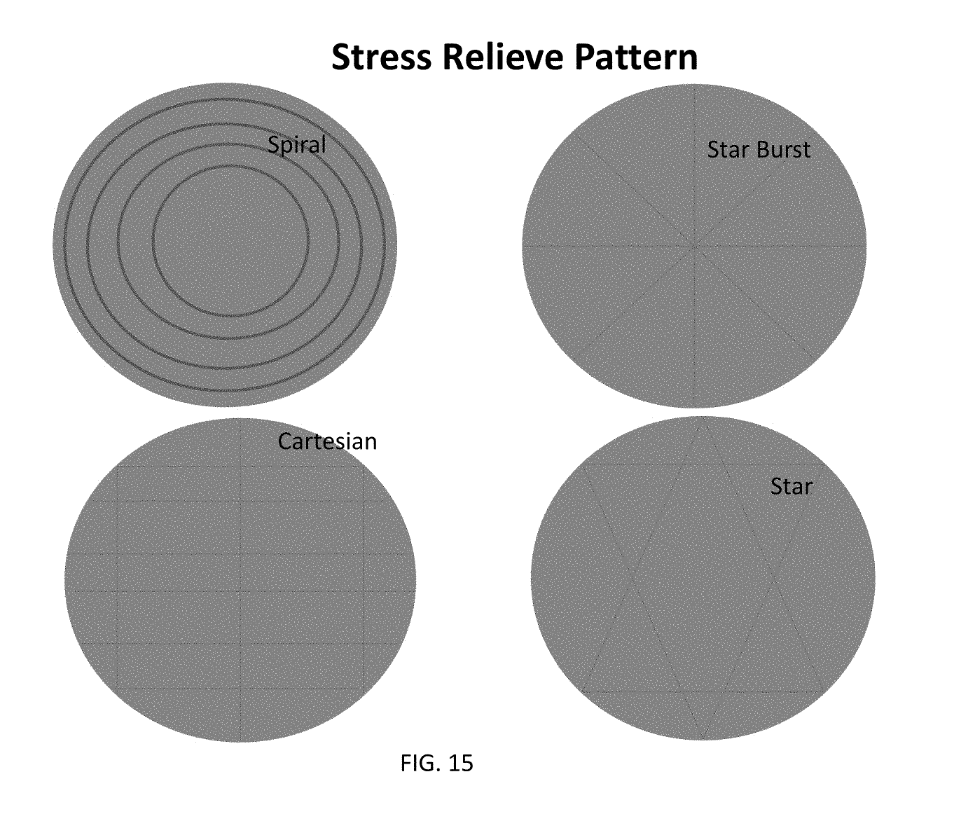

In accordance with the invention, substrate 10 is formed of a copper or copper-alloy layer 13 and a substrate protective layer 11. Substrate 10 may be a substrate with or without a stress relief design and/or with or without a compensate design. Exemplary stress relief patterns are shown in FIG. 15, and may include a spiral pattern, star burst pattern, cartesian pattern, star pattern, or any other suitable pattern which, like the exemplary patterns, relieves stress in the design. Protective layer 11 may be formed from any suitable material, including a compound, polyimide, resin, inert metal layer, or any other suitable layer. It should be noted that the any other suitable electrically conductive substrate may be used in place of copper.

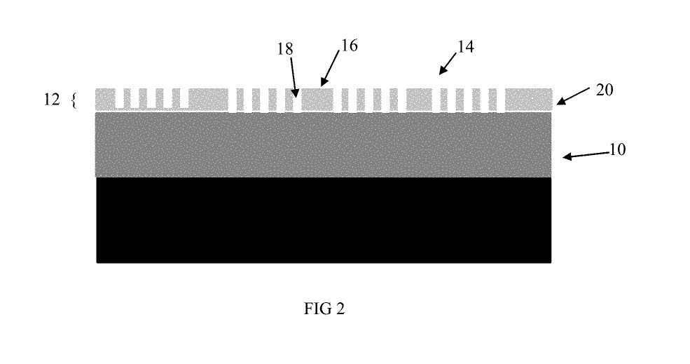

Referring now to FIG. 2, a first pattern 12 may be applied to a copper layer 13 side of the substrate 10 by a known process such as photoetching or any other suitable process. As shown, first pattern 12 is applied to a first side 14 of substrate 10, forming a pattern of electrically conductive circuit traces 17. Circuit traces 17 are formed of lands 16 and channels 18. Lands 16 are formed from copper layer 13 treated with photoresist, while channels 18 are formed within the copper layer 13 after being exposed to a suitable etchant. Channels 18 may be formed by any suitable process, such as chemical etching or laser ablation.

As shown in FIG. 2, side 14 may be coated with a chemical resist 20 in the desired portions for forming the lands 16, and the first side 14 is exposed to etchant for a period of time to form channels 18 within gaps of photoresist. The channels 18 may have a depth of 45-65% of the thickness of the electronically conductive substrate, but depths ranging from 40-99% are also contemplated by the invention.

In accordance with the invention, the lands 16 are formed in an array pattern and are configured for bonding to external circuitry, such as an array of bond pads on an external printed circuit board. In one embodiment, lands 16 may be finished or plated with solderable materials, including, but not limited to, solder paste, Sn, Ag, Au, NiAu, or any other suitable solderable material, in order to facilitate attachment by soldering to an external circuit board.

Thus, substrate 10 is coated with chemical resist 20, and then exposed to light. The substrate 10 is then developed. Etching, including any suitable form of etching, is then performed to form the channels 18 and lands 16.

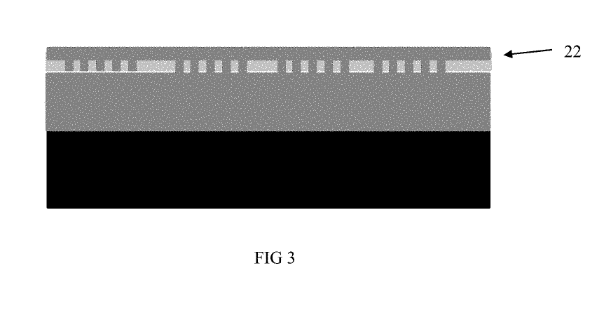

Referring to FIG. 3, copper plating is applied to the photoresist 20 using sputter technology. This causes the channels 18 to be filled with copper using electroplating. As illustrated, a copper plating 22 now resides at the top.

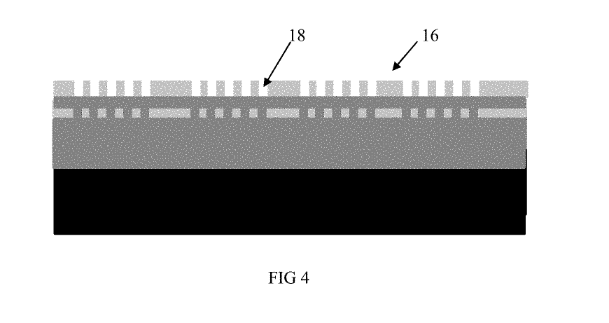

In reference to FIG. 4, a second pattern of photoresist 24 is applied to the substrate 10. A second chemical resist coating 24 is applied to the substrate 10, and the surface is exposed to a suitable etchant for a period of time suitable to form a series of lands 16 and channels 18. The second pattern 24 is then exposed to light and developed.

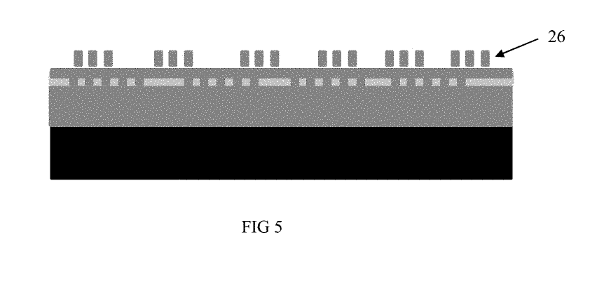

FIG. 5 illustrates application of another layer of copper, and the formation of metal pillar bumps 26 (chip attach sites). The photoresist is stripped and removed. The chip attach sites 26 are electrically interconnected to the lands 16 by routing circuits. Each chip attach site 26 protrudes from the surface of substrate 10.

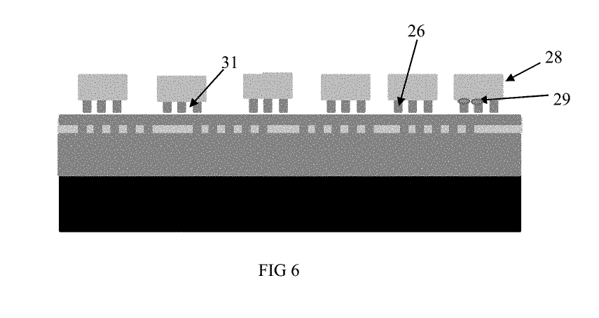

Each chip attach site 26 attaches to an Input/Output (I/O) pad on a semiconductor device 28, as shown in FIG. 6. The semiconductor device/die 28 is interconnected to the chip attach sites 26 by a flip chip method. Thus, no intervening wire bond or tape automated bonding tape is utilized. The semiconductor device 28 is directly electrically interconnected to chip attach sites 26 by solder bumps. Chip attach sites 26 are disposed opposite the input/output pads of device 28, and are connected by interconnect bumps 29. Interconnect bumps 29 may be formed from solders, typically an alloy of gold, tin and lead, with a melting temperature between 180 degrees and 240 degrees Celsius. The I/O bumps 29 are microbumps that are formed on the device 28.

Chip attach sites 26 extend upward from the substrate 10, forming a space 31 between the semiconductor device 28 and the substrate. This facilitates flow of a second protective layer 30 to encapsulate the semiconductor device.

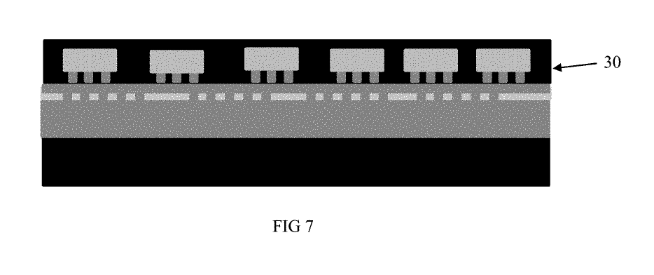

With reference to FIG. 7, protective layer 30 encapsulates semiconductor device 28 and pillars 26, causing the entire semiconductor package to be encased. The protective layer 30 is electrically non-conductive, and preferably formed from a polymer molding resin. The protective layer 30 may be identical or substantially identical to protective layer 11, or may be entirely different.

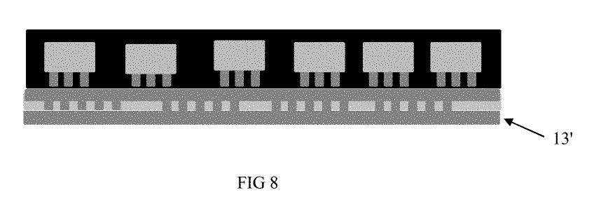

As shown in FIG. 8, the second side 32 of substrate 10, the backside, is ground down to remove a substantial portion, or all, of the protective layer 11. The underside of the copper layer, denoted as 13′, is then thinned and/or etched. The underside 13′ is thinned using a thinning process. Alternatively, a carrier removal process is used to thin or etch the underside using a suitable process such as back grinding, planarization, or etching.

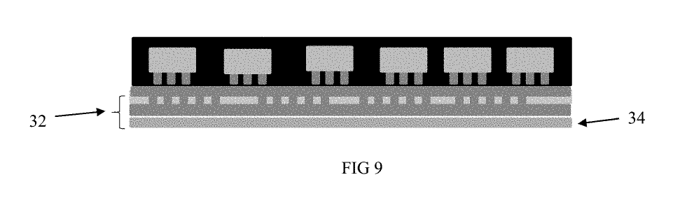

Referring to FIG. 9, a ball grid array pattern 34 is applied to the second side 32. The BGA provides a plurality of interconnects. The second side 32 is thus coated with chemical resist coating 20, and is then exposed to light and developed.

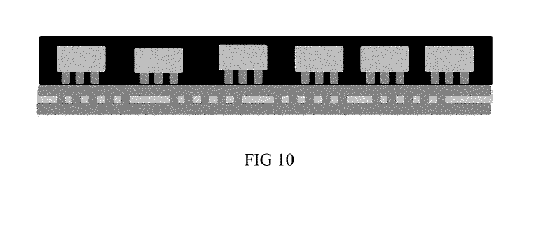

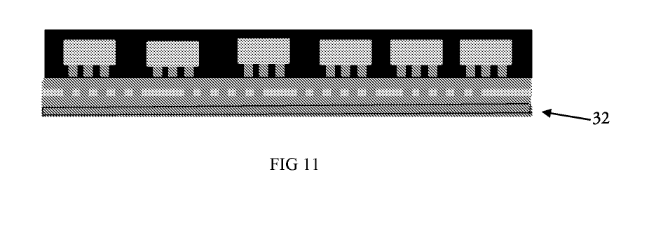

In reference now to FIG. 10, the copper etching and photoresist stripping is performed, forming a series of shallow channels 18 on second side 32. A solder mask coating 36, shown in FIG. 11, is then applied to second side 36.

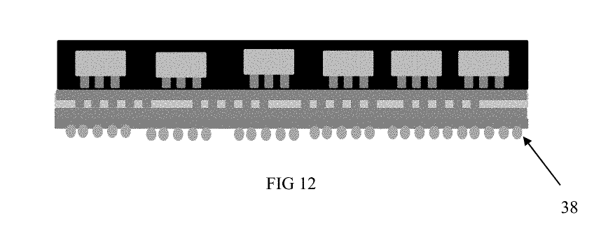

As shown in FIG. 12, a plurality of solder balls 38 are applied to the underside of solder mask coating 36.

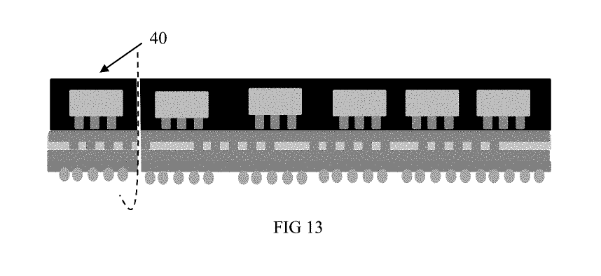

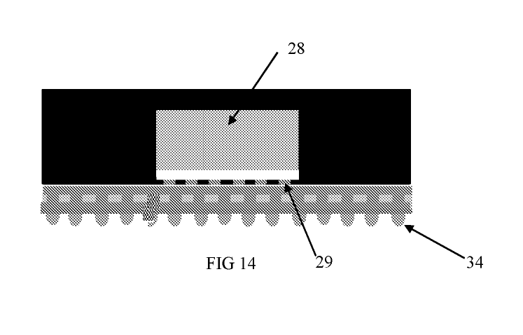

In reference to FIG. 13, unit singulation is performed, separating single die units 40 from the remainder of the wafer. Referring to FIG. 14, a close-up view illustrates the die 28 connected to the chip attach site 26 by microbump 29, with the BGA 34 at the bottom.

In accordance with the invention, interconnect bumps 29, such as those illustrated in FIG. 6, are formed at the substrate carrier. Utilizing a standard flip chip process, the semiconductor device 28 is attached directly to the interconnect bumps 29, which binds semiconductor device directly to the chip attach site 26. This eliminates shifting of the semiconductor device during the process of applying the protective layer on a reconstituted wafer, and reduces damage from handling.

The unique stress relief pattern implemented on the backside/second side 32 compensates and controls the thermomechanical stress build up due to high temperature processes. This removes the need for a de-bonding process of reconstituted wafer from the carrier which would otherwise be required.

The inventive process allows for use of lower costs materials on the I/O sides, and expensive chip wastage due to process yield loss is reduced.

One or more embodiments of the present invention have been described. Nevertheless, it will be understood that various modifications may be made without departing from the spirit and scope of the invention. Accordingly, other embodiments are within the scope of the following claims.

1. A method for manufacturing substrate based fan-out wafer level packaging, comprising:
providing a substrate;
applying a first photoresist pattern;
depositing copper or a copper alloy on said first photoresist pattern;
applying a second photoresist pattern;
forming chip attach site pillars by depositing a layer of copper or copper alloy on said second photoresist pattern;
attaching a semiconductor device via a flip chip bonding, the attaching including:
forming a plurality of interconnect bumps between the semiconductor device and the chip attach site; and
forming a space between the semiconductor device and the substrate;
encapsulating the semiconductor device with a protective layer;
thinning a second side of the substrate, the thinning including copper etching and thinning;
applying a ball grid array pattern on the second side, the ball grid array pattern including a stress relief pattern, the stress relief pattern implemented on the ball grid array pattern and forming a relief of stress for the packaging;
etching the second side with copper;
applying a solder mask coating;
attaching a plurality of ball drops; and
singulating a unit.

2. The method of claim 1 wherein the substrate includes copper and a protective layer.

3. The method of claim 1 wherein the first pattern comprises a plurality of lands and channels.

4. The method of claim 3 wherein the first pattern is applied to a first side, the method further comprising:
coating the first side with a chemical resist to form a plurality of lands; and
exposing the first to etchant to form channels.

5. (canceled)

6. (canceled)

7. A substrate based fan-out wafer level packaging, comprising:
a substrate;
a first photoresist pattern, the first photoresist pattern adapted to be applied to the substrate;
a copper or copper alloy layer, the copper or copper alloy layer adapted to be applied on top of the first photoresist pattern;
a second photoresist pattern, the second photoresist pattern adapted to be applied above the copper or copper alloy layer;
a plurality of chip attach site pillars, the chip attach site pillars including a plurality of interconnect bumps and formed on top of said second photoresist pattern;
a semiconductor device, the semiconductor device adapted to be placed above the interconnect bumps;
a protective layer, the protective layer forming an encapsulant around the semiconductor device;
a ball grid array pattern adapted to be applied to a second side of the substrate;
a solder mask coating applied below the ball grid array pattern; and
a plurality of solder balls attached to the solder mask coating.

8. The packaging of claim 7 wherein the protective layer is selected from a group consisting of a compound, polyimide, resin, or inert metal layer.

9. The packaging of claim 7 wherein the substrate includes a stress relief design.

10. The packaging of claim 9 wherein the stress relief design is a star design.

11. The packaging of claim 9 wherein the stress relief design is a cartesian design.

12. The packaging of claim 7 further comprising a thinning process.

13. The packaging of claim 12 further comprising a carrier removal process.

14. The method of claim 1 wherein the stress relief pattern is formed in a spiral pattern.

15. The method of claim 1 wherein the stress relief pattern is formed in a star burst pattern.

16. The method of claim 1 wherein the stress relief pattern is formed in a cartesian pattern.

17. The method of claim 1 wherein the stress relief pattern is formed in a star pattern.
